(19) United States
(12) Patent Application Publication
(10) Pub. No.: US 2008/0203478 A1
(43) Pub. Date: Aug. 28, 2008

(54) High Frequency Switch With Low Loss, Low Harmonics, And Improved Linearity Performance

(76) Inventors: Dima Prikhodko, Burlington, MA (US); Jerod F. Mason, Bedford, MA (US); Gouliang Zhou, Ashland, MA (US); Gene A. Tkachenko, Belmont, MA (US); Steven C. Sprinkle, Hampstead, NH (US); Oleksiy Klimashov, Burlington, MA (US)

Correspondence Address: Michael J. Tempel;SMITH FROHWEIN TEMPEL GREENLEE BLAHA LLC, Suite 700, Two Ravinia Drive, Atlanta, GA, 30356, US

(21) Appl. No.: 12/035,519

(22) Filed: Feb. 22, 2008

Related U.S. Application Data
(60) Provisional application No. 60/891,239, filed on Feb. 23, 2007.

(51) Int. Cl. H01L 29/786; H01L 21/336

(52) U.S. Cl. 257/347; 438/151; 257/E29.273; 257/E21.411

(57) ABSTRACT

A switch element includes a field effect transistor (FET) structure formed on a substrate, the FET structure having a drain, a gate and a source, the drain having a drain capacitance, the gate having a gate capacitance, the source having a source capacitance and an electrical connection to couple the drain capacitance, gate capacitance and the source capacitance to the substrate.

### CROSS REFERENCE TO RELATED APPLICATION

This application claims priority to co-pending U.S. provisional application entitled, “HIGH FREQUENCY SWITCH WITH Low Loss Low HARMONICS AND IMPROVED LINEARITY PERFORMANCE,” having Ser. No. 60/891,239, filed on Feb. 23, 2007, and which is entirely incorporated herein by reference.

### BACKGROUND

Portable communication devices, such as cellular telephones, typically are required to operate over a number of different communication bands. These so called “multi-band” communication devices use one or more instances of transmit and receive circuitry to generate and amplify the transmit and receive signals. However, these communication devices usually employ a single antenna to transmit and receive the signals over the various communication bands.

The antenna in such communication devices is typically connected to the transmit and receive circuitry through switching circuitry, such as a duplexer or a diplexer, or through an isolated switch element, sometimes referred to as a “transmit/receive switch” or an “antenna switch.” The switching circuitry or the isolated switch element must effectively isolate the transmit signal from the receive signal. Isolating the transmit signal from the receive signal becomes more problematic in a multiple band communications device where the transmit frequency of one communication band might overlap with the receive frequency of a different communication band.

FIG. 1 is a schematic diagram illustrating a portion of a prior art transceiver 10 showing a blocking signal interfering with a received signal. The transceiver 10 includes an antenna 12 coupled via connection 14 to an antenna switch 16. The antenna switch 16 is coupled via connection 17 to a phase shifter 18. The phase shifter 18 is coupled via bi-directional connection 19 to a transmit filter 21 and to a receive filter 22. The antenna switch 16, phase shifter 18, transmit filter 21, and receive filter 22 form a duplexer. The transmit filter 21 receives an amplified output of a power amplifier 25 via connection 24. The receive filter 22 delivers the receive signal via connection 27 to a low noise amplifier 28. The remainder of the transmit circuitry, the remainder of the receive circuitry and the baseband processing elements are omitted from FIG. 1 for simplicity.

The antenna switch 16, the transmit filter 21 and the receive filter 22 isolate the transmit signal from the receive signal. When implementing a 2G or 3G transceiver, linearity and physical size of the antenna switch are significant design factors. Linearity is usually defined by what is referred to as a third order intermodulation product, referred to as IMD3. As shown in FIG. 1, the nature of this effect is that mixing products of the TX signal with an outside blocker signal fall into the RX band, as shown using the graphical illustration 41 and specifically, the vector 46. The IMD signal may deteriorate the sensitivity of the receiver if the antenna switch 18 allows a sufficiently high IMD signal. The antenna switch 16 may be separated from the antenna 12 by a matching or electrostatic discharge (ESD) network (not shown).

The largest factor in IMD performance of the antenna switch 16 is the nonlinear capacitance of the off branches of the switch. As shown in FIG. 2, the antenna switch 16 comprises a number of branches 22, 24, 26 and 28, with the number of branches dependent upon the number of frequency bands implemented in the transceiver. In this example the branches 24, 26 and 28 are “off” and the branch 22 is “on”. In this example, the branches 22, 24, 26 and 28 are implemented using field effect transistors (FETs) and the gate, source and drain connections are shown in FIG. 2. The parasitic capacitances of the off branches 24, 26 and 28 become more linear at more negative Vgs(Vds) voltages. This is one reason that conventional 2G/3G solutions are implemented using charge pumps. In this configuration, the ON branch 22 (TX1) is biased by VH voltage, settling down the potential on all drain sources as VH-VF, where VF is a diode voltage which is usually equal to 0.3V. The OFF branches (TX2-TXn) are biased off by the voltage VL-(VH-VF).

FIG. 3 is a diagram illustrating the operating point of each transistor in an off branch of FIG. 2. In FIG. 3, Vp is a pinchoff voltage, VRF is an antenna radio frequency (RF) swing, indicated using reference numeral 32, and n is a number of series stacked transistors in each antenna branch. To overcome severe harmonics and IMD distortion it is desirable to keep the operating area below the pinch off voltage:

$${V}_{L} - ( {V}_{H} - {V}_{F} ) + \frac{{V}_{RF}}{2} < {V}_{P}$$

From this equation we can see that the minimum number of the series transistors should be

$$n > \frac{2 {( {V}_{P} + {V}_{H} - {V}_{F} - {V}_{L} )}^{2}}{{P}_{IN} {Z}_{L}} , \qquad ( Eq . 1 )$$

where P_{IN} is the output power, Z_{L} is the output impedance, V_{P} is the pinchoff voltage, V_{H} and V_{L} are the high and low bias and V_{F} is the junction voltage in the ON state which is ˜0.3V.

In an ON branch, the size of the transistor should be chosen such that:

$${I}_{dss} = \sqrt{\frac{2 {P}_{IN}}{{Z}_{L}}} \qquad ( Eq . 2 )$$

where I_{dds} is the saturation current of the FET. With proper scaling the contribution to linearity degradation of the ON branch can be minimized.

The OFF branch case is more complicated than the ON branch case. Even if OFF branch FETs are operating below the pinchoff voltage, linear distortion due to the nonlinear behavior of the parasitic capacitances is still evident.

The typical cross section of a pseudomorphic high electron mobility transistor (PHEMT) device is shown in FIG. 4. The transistor 50 generally includes a semi-insulating substrate 52 over which a buffer layer 54 fabricated from a dielectric material is formed. A channel 61 comprising a delta doping region 56 and an indium gallium arsenide (InGaAs) layer 57 is formed over the buffer layer 54. A spacer layer 62 including a delta doping region 58 and an aluminum gallium arsenide (AlGaAs) layer 59 is formed over the channel 61.

An etch stop layer 65 is formed over the spacer layer 62. An N− layer 64 is also formed over the etch stop layer 65. Another etch stop layer 66 is formed over the N− layer 64. An N+ layer 68 is formed over the etch stop layer 66.

The layers 68, 64, 59, 58, 57, 56 and 54 form a switching device, a plurality of which form the antenna switch described above. Ohmic metal is deposited to form a drain 74 and a source 71. Similarly, after a suitable etching step down to the etch stop layer 65, gate metal is deposited to form a gate 72.

If the condition that the most dominant contributor in IMD will be nonlinear gate-source/drain and substrate—gate/source/drain capacitances is satisfied, then the equivalent model of an OFF transistor, including the most dominant contributors to IMD/harmonics, is shown in FIG. 5. The typical behavior of the gate-source/drain capacitance is shown in FIG. 6.

Referring to FIG. 5, the most dominant contributors to the linearity degradation are gate—drain/source and drain/source—substrate capacitances. Generally speaking in some areas of operation they can be described by the polynomial expression:

C(Vⱼ)=b₀+b₁Vⱼ+b₂Vⱼ² (Eq. 3)

where Vⱼ is a RF applied voltage and b₀,b₁, b₂ are the coefficients. The current generated by these capacitances due to a voltage swing Vⱼ is:

$$i ( {V}_{j} ) = C ( {V}_{j} ) \frac{d {V}_{j}}{d t} \qquad ( Eq . 4 )$$

IMD measurements are typically performed by applying two tone signals at the antenna with the frequencies ω₁,ω₂ and amplitude V_{RF01}, V_{RF02}:

V_{RF}(ωt)=V_{RF01} cos(ω₁t)+V_{RF02} cos(ω₂t) (Eq. 5)

The RF voltage across each junction of the OFF FET is:

$${V}_{j} ( ω t ) = {A}_{1} cos ( {ω}_{1} t ) + {A}_{2} cos ( {ω}_{2} t ) \\ where {A}_{1} = \frac{{V}_{RF 01}}{2 n} and {A}_{2} = \frac{{V}_{RF 02}}{2 n} \qquad ( Eq . 6 )$$

After substituting Equations (6) and (3) in Equation (4) and rearranging terms, the following are the intermodulation products of the currents generated in an OFF FET:

$$\begin{matrix}ω = {ω}_{1} \pm {ω}_{2} \text{:} - \frac{1}{2} {A}_{1} {A}_{2} {b}_{1} [ ( {ω}_{1} - {ω}_{2} ) sin ( {ω}_{1} - {ω}_{2} ) + ( {ω}_{1} + {ω}_{2} ) sin ( {ω}_{1} + {ω}_{2} ) ] & ( Eq . 7 ) \\ 2 {ω}_{1} \pm {ω}_{2} \text{:} - \frac{1}{4} {A}_{1}^{2} {A}_{2} {b}_{2} [ ( 2 {ω}_{1} - {ω}_{2} ) sin ( 2 {ω}_{1} - {ω}_{2} ) + ( 2 {ω}_{1} + {ω}_{2} ) sin ( 2 {ω}_{1} + {ω}_{2} ) ] & ( Eq . 8 ) \\ {ω}_{1} \pm 2 {ω}_{2} \text{:} - \frac{1}{4} {A}_{1} {A}_{2}^{2} {b}_{2} [ ( {ω}_{1} - 2 {ω}_{2} ) sin ( {ω}_{1} - 2 {ω}_{2} ) + ( {ω}_{1} + 2 {ω}_{2} ) sin ( {ω}_{1} + 2 {ω}_{2} ) ] & ( Eq . 9 )\end{matrix}$$

The following fundamental components are also included:

$$ω = {ω}_{1} , {ω}_{2} \text{:} \begin{matrix}- {ω}_{1} {A}_{1} sin ( {ω}_{1} t ) [ {b}_{0} + \frac{1}{2} {A}_{2}^{2} {b}_{2} + \frac{1}{4} {A}_{1}^{2} {b}_{2} ] - \\ - {ω}_{2} {A}_{2} sin ( {ω}_{2} t ) [ {b}_{0} + \frac{1}{2} {A}_{1}^{2} {b}_{2} + \frac{1}{4} {A}_{2}^{2} {b}_{2} ]\end{matrix} \qquad ( Eq . 10 )$$

As shown in equations (7) to (9) the most significant contributor to IMD is a quadratic coefficient b₂: the higher quadratic term in C(Vⱼ) dependency, the higher the intermodulation product.

In FIG. 6 it is shown that by increasing VH the performance of a transistor moves away from the nonlinear region of Cgs(Cgd) capacitance and improves IMD performance. As mentioned above, other than Cgs and Cgd nonlinearities, substrate—drain/source/gate (Cdsub, Cssub, Cgsub) capacitances make a significant contribution to IMD. The most common way to linearize C(Vⱼ) is to use a higher bias voltage. This is applicable for the drain/source—gate capacitances but has a minimal effect on the drain/source—substrate capacitances.

Therefore, it would be desirable to have an antenna switch that provides high linearity and low loss in a small area.

### SUMMARY

Embodiments of the invention include a switch element, including a field effect transistor (FET) structure formed on a substrate, the FET structure having a drain, a gate and a source, the drain having a drain capacitance, the gate having a gate capacitance, the source having a source capacitance and an electrical connection to couple the drain capacitance, gate capacitance and the source capacitance to the substrate.

Other embodiments are also provided. Other systems, methods, features, and advantages of the invention will be or become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE FIGURES

The invention can be better understood with reference to the following figures. The components within the figures are not necessarily to scale, emphasis instead being placed upon clearly illustrating the principles of the invention. Moreover, in the figures, like reference numerals designate corresponding parts throughout the different views.

FIG. 1 is a schematic diagram illustrating a portion of a prior art transceiver showing a blocking signal interfering with a received signal.

FIG. 2 is a schematic diagram illustrating a prior art antenna switch.

FIG. 3 is a diagram illustrating the operating point of each transistor in an off branch of FIG. 2.

FIG. 4 is a cross-section of a typical PHEMT device.

FIG. 5 is a circuit-equivalent model of an OFF transistor, including the most dominant contributors to IMD/harmonics.

FIG. 6 is a diagram illustrating the operating point of each transistor in an off branch of FIG. 2.

FIG. 7 is a schematic diagram illustrating a portion of a transceiver including an embodiment of a high frequency low loss switch.

FIG. 8 is a schematic diagram illustrating an embodiment of the high frequency, low loss switch.

FIGS. 9A and 9B are diagrams showing example IMD2 and IMD3 performance, respectively, for a nine throw GSM/CDMA antenna switch.

FIG. 10 is a schematic diagram illustrating an embodiment of a high frequency, low loss switch.

FIG. 11 is a cross-sectional diagram illustrating an embodiment of a transistor device that can be used to fabricate a high frequency, low loss switch.

FIG. 12 is a cross-sectional diagram illustrating an alternative embodiment of a transistor device that can be used to fabricate a high frequency, low loss switch.

FIG. 13 is a cross-sectional diagram illustrating another alternative embodiment of a transistor device that can be used to fabricate a high frequency, low loss switch.

FIG. 14 is a cross-sectional diagram illustrating another alternative embodiment of a transistor device that can be used to fabricate a high frequency, low loss switch.

FIG. 15 is a cross-sectional diagram illustrating another alternative embodiment of a transistor device that can be used to fabricate a high frequency, low loss switch.

FIG. 16 is a cross-sectional diagram illustrating another alternative embodiment of a transistor device that can be used to fabricate a high frequency, low loss switch.

FIG. 17 is a cross-sectional diagram illustrating another alternative embodiment of a transistor device that can be used to fabricate a high frequency, low loss switch.

FIG. 18 is a flow chart illustrating an example of making an embodiment of a high frequency, low loss switch element.

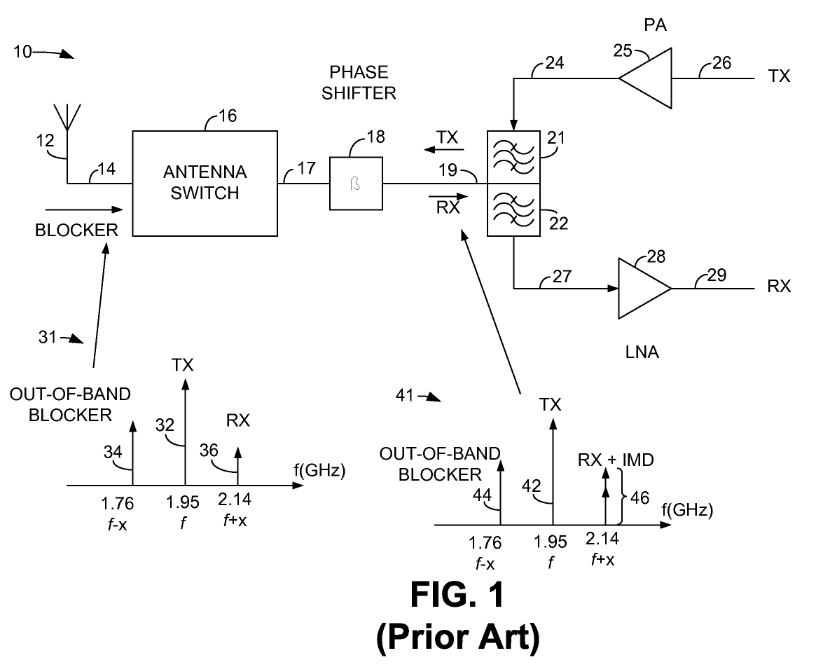

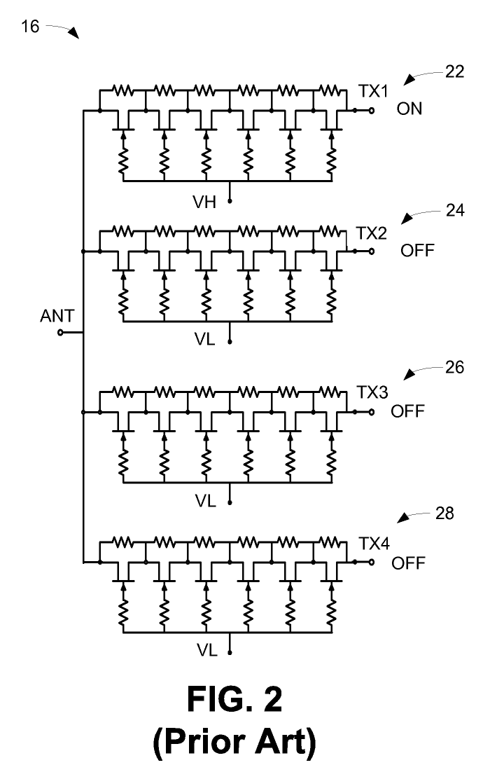

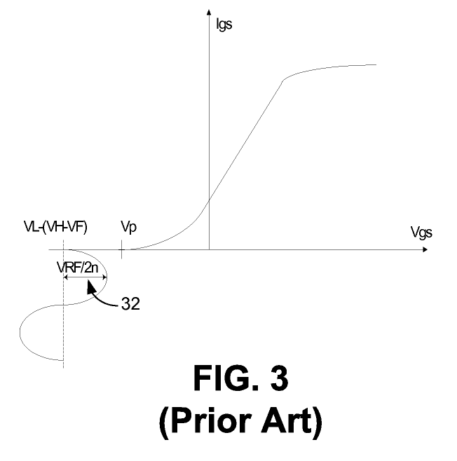

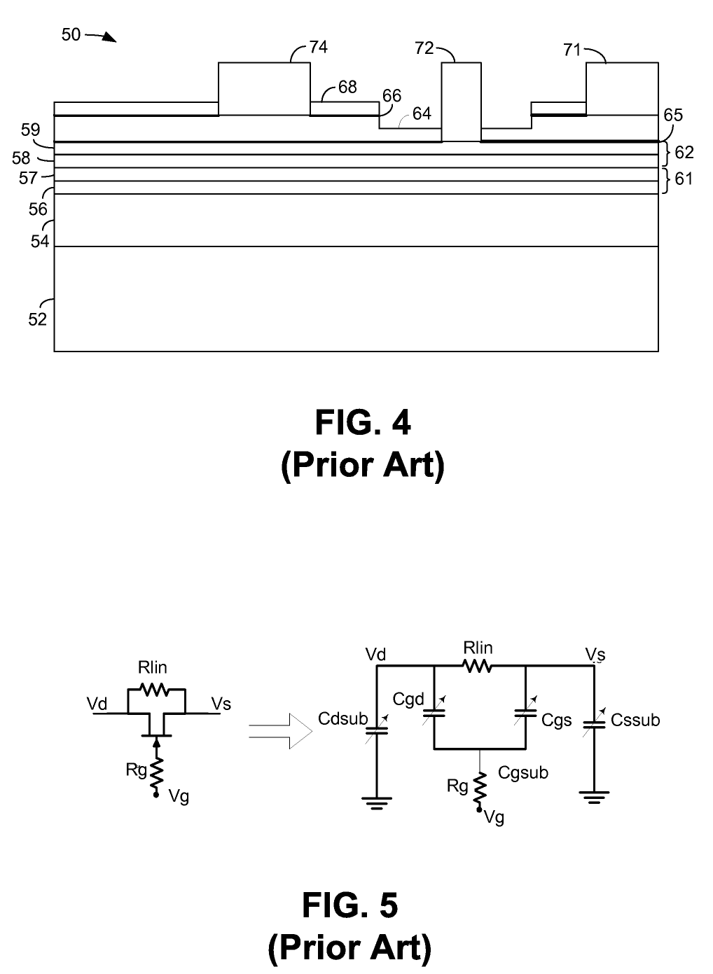

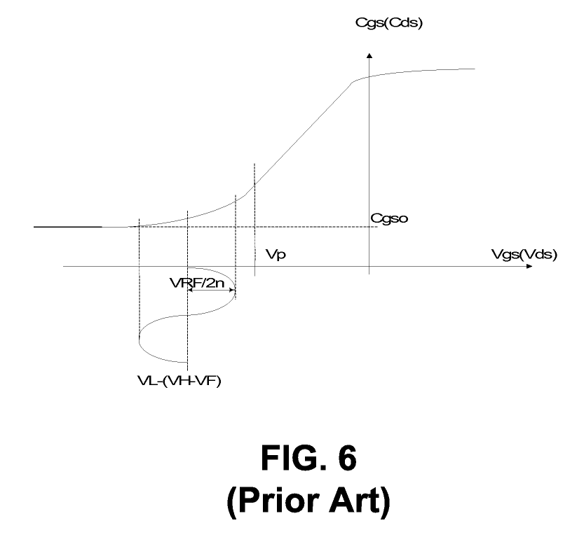

### DETAILED DESCRIPTION

Although described with particular reference to a portable transceiver, the high frequency switch with low loss, low harmonics and improved linearity performance (also referred to herein as the “high frequency, low loss switch”) can be implemented in any transceiver device in which a compact high frequency, low loss antenna switch is desirable.

The high frequency, low loss switch is generally implemented in hardware. However, one or more of the signals that control the high frequency, low loss switch can be implemented in software, or a combination of hardware and software. When implemented in hardware, the high frequency, low loss switch can be implemented using specialized hardware elements. When one or more of the control signals for the high frequency, low loss switch are generated at least partially in software, the software portion can be used to precisely control the operating aspects of various components in high frequency, low loss switch. The software can be stored in a memory and executed by a suitable instruction execution system (microprocessor). The hardware implementation of the high frequency, low loss switch can include any or a combination of the following technologies, which are all well known in the art: discrete electronic components, a discrete logic circuit(s) having logic gates for implementing logic functions upon data signals, an application specific integrated circuit having appropriate logic gates, a programmable gate array(s) (PGA), a field programmable gate array (FPGA), a separate, specially designed integrated circuit for biasing purposes, etc.

The software for the high frequency, low loss switch comprises an ordered listing of executable instructions for implementing logical functions, and can be embodied in any computer-readable medium for use by or in connection with an instruction execution system, apparatus, or device, such as a computer-based system, processor-containing system, or other system that can fetch the instructions from the instruction execution system, apparatus, or device and execute the instructions.

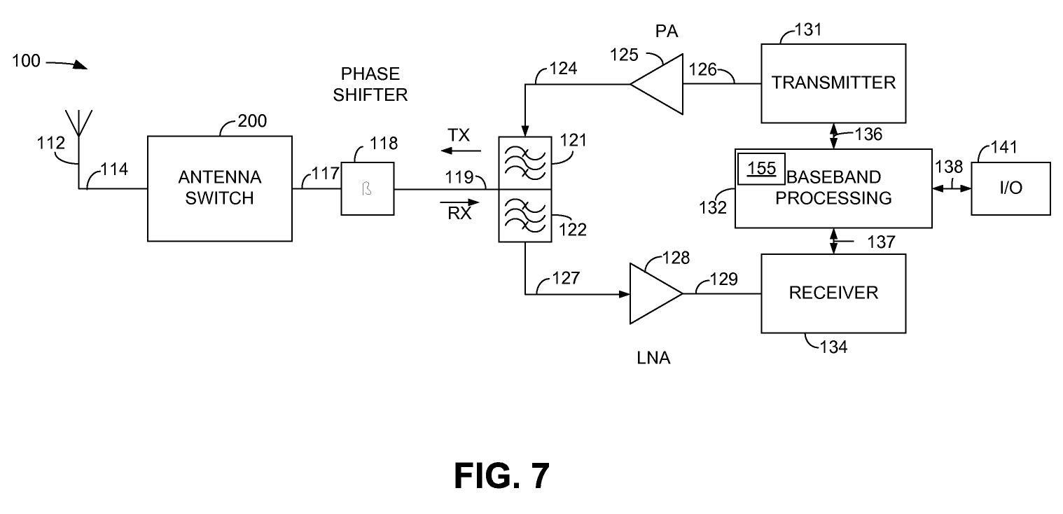

FIG. 7 is a schematic diagram illustrating a portion of a transceiver 100 including an embodiment of a high frequency, low loss switch 200. The transceiver 100 includes an antenna 112 coupled via connection 114 to a high frequency, low loss switch antenna switch 200. The high frequency, low loss antenna switch 200 is coupled via connection 117 to a phase shift element 118. The phase shift element 118 is coupled via bi-directional connection 119 to a transmit filter 121 and to a receive filter 122. The transmit filter 121 receives an amplified output of a power amplifier 125 via connection 124. A transmitter 131 supplies the transmit signal via connection 126 to the power amplifier 125.

The receive filter 122 delivers the receive signal via connection 127 to a low noise amplifier 128. The output of the low noise amplifier 128 is supplied via connection 129 to a receiver 134. The transmitter 131 and the receiver 134 are shown for illustrative purposes only. Various configurations and implementation of a transmitter and receiver are known to those having ordinary skill in the art and all such implementations are contemplated herein. The transceiver 100 also comprises baseband processing circuitry 132 coupled to the transmitter 131 via connection 136 and coupled to the receiver 134 via connection 137. The baseband processing circuitry performs baseband signal processing for the transmit signal and for the receive signal as known in the art. If one or more portions or aspects of the compact low loss switch 200 are implemented in software, then the baseband processing circuitry includes the high frequency, low loss switch software 155.

The baseband processing circuitry 132 is coupled to an input/output element 141 via connection 138. In an example in which the transceiver 100 is part of a portable communications device, such as a cellular-type telephone, the input/output element 141 comprises a microphone, speaker, keyboard, pointing device, or other interface elements.

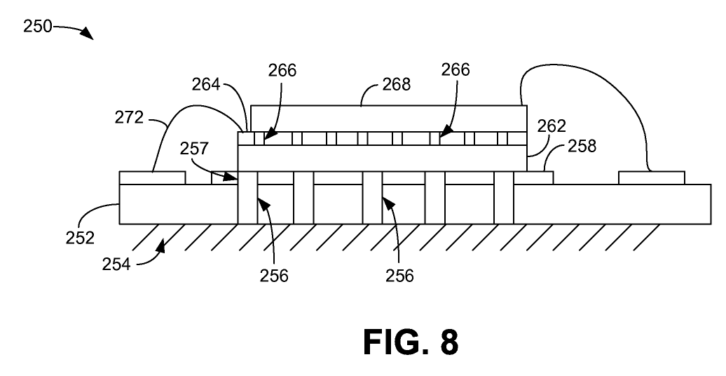

FIG. 8 is a schematic diagram illustrating an embodiment of the high frequency, low loss switch. The embodiment shown in FIG. 8 employs what is referred to as a “stacked die” approach. The term “stacked die” refers to a multi-layer structure in which a “plate” is located between a semiconductor die and a laminate, such as a printed circuit board (PCB), and in which the semiconductor die is separated from a switch die by another “plate.”

A dielectric substrate 252 includes one or more vias 256. The dielectric substrate is generally a multi-layer laminate structure, such as a printed circuit board (PCB). The dielectric substrate 252 is directly connected to a ground layer 254. A first plate 258 is located over the dielectric substrate 252. The first plate 258 includes vias 257. The vias 257 correspond to the vias 256 in the dielectric substrate 252, but this is not a requirement. The first plate 258 is typically fabricated from a thermally conductive material, such as a metal, and is sometimes referred to as a “grounded paddle.”

An electrically insulating, thermally conductive die 262 is located over the first plate 258. A second plate 264 is located over the die 262. The second plate 264 may include vias 266 and is typically fabricated from a metal material. A switch die 268 is located over the second plate 264.

The first plate 258 provides a heat path to ground 254. The die 262 acts as both an insulator between the second plate 264 and the first plate 258 and also provides a heat path to the first plate 258. To improve losses and power handling capability, a path to ground is created from the switch die 268, through the second plate 264, the die 262 and the first plate 258 through the vias 256. This path provides for heat dissipation and allows the capacitances Cdsub, Cssub and Cgsub (FIG. 5) to be biased off, by coupling the capacitances Cdsub, Cssub and Cgsub (FIG. 5) to the substrate 252. The die 262 can be fabricated using gallium arsenide (GaAs), silicon (Si) or another material with adequate thermal conductivity and electrical insulative properties. The second plate 264 may include vias 266 to provide proper thermal conductivity and could be connected to an external pin by a bond wire 272 or by a via etched through the backside depending on the laminate layout.

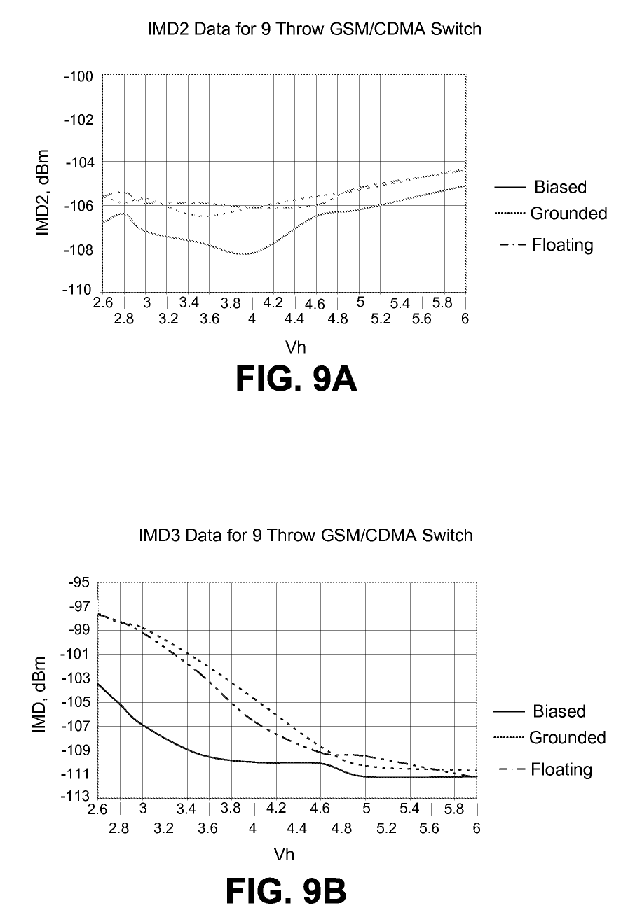

FIGS. 9A and 9B are diagrams showing example IMD2 and IMD3 performance, respectively, for a nine throw GSS/CDMA antenna switch. FIGS. 9A and 9B illustrate that by applying a positive potential to the second plate 264 (FIG. 8), the substrate capacitances are shifted to the more linear region thus significantly improving IMD2/3 performance.

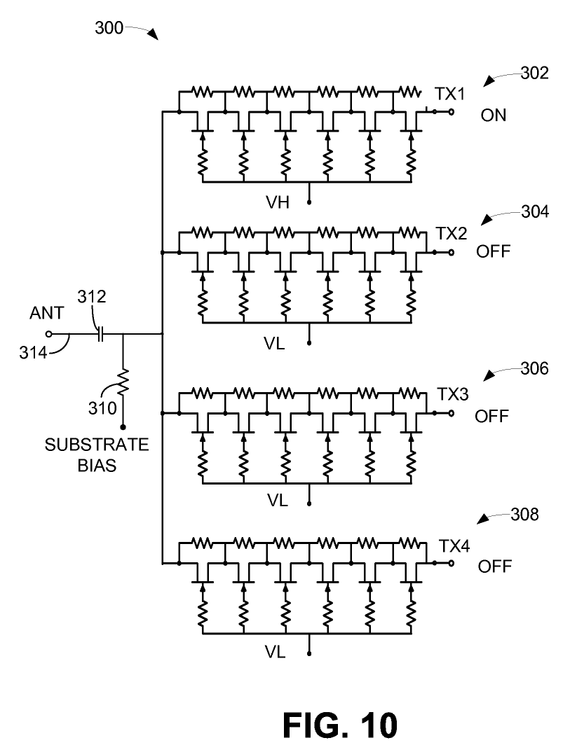

FIG. 10 is a schematic diagram illustrating an embodiment of a high frequency, low loss antenna switch 300. The antenna switch 300 comprises a number of branches 302, 304, 306 and 308, with the number of branches dependent upon the number of frequency bands implemented in the transceiver. In this example the branches 304, 306 and 308 are “off” and the branch 302 is “on”. In this example, the branches 302, 304, 306 and 308 are implemented using field effect transistors (FETs) and the gate, source and drain connections are shown in FIG. 10. In accordance with an embodiment of the high frequency, low loss switch, the antenna port 314 includes a resistance 310 and a capacitance 312. The resistance 310 includes a connection to bias the substrate as described above in FIG. 8.

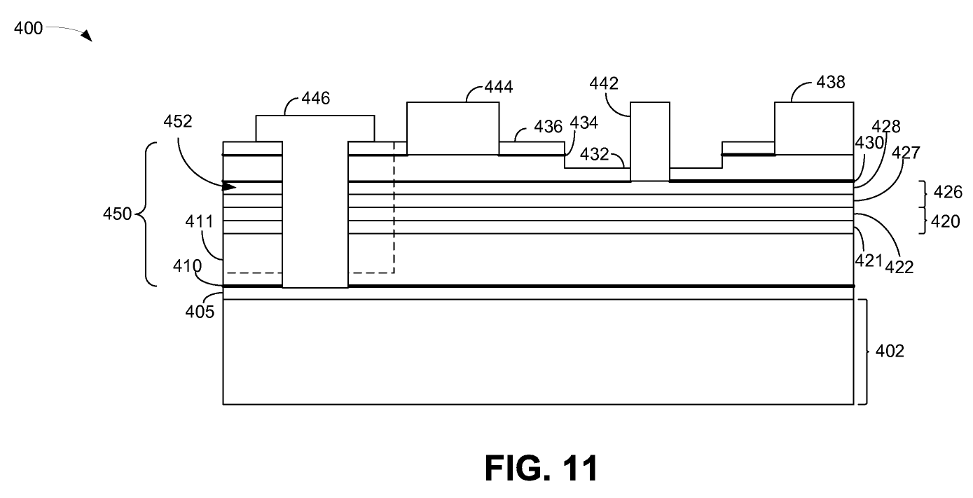

FIG. 11 is a cross-sectional diagram illustrating an embodiment of a transistor device that can be used to fabricate an alternative embodiment of a high frequency, low loss switch.

The transistor device 400 is illustrated as a pseudomorphic high electron mobility transistor (PHEMT) fabricated using materials in the gallium arsenide material system, but other structures using different material systems are possible. The transistor device 400 includes a semi-insulating substrate 402 over which a conductive n type, or p type, layer 405 is formed. The conductive layer 405 can be constructed from gallium arsenide (GaAs), indium gallium arsenide (InGaAs) or other material systems. An etch stop layer 410 is formed over the conductive layer 405. A buffer layer 411, fabricated from a dielectric material, is formed over the etch stop layer 410. A channel 420, comprising a delta doping region 421 and an indium gallium arsenide (InGaAs) layer 422, is formed over the buffer layer 411. A spacer layer 426, including a delta doping region 427 and an aluminum gallium arsenide (AlGaAs) layer 428, is formed over the channel 420.

An etch stop layer 430 is formed over the spacer layer 426. An N− layer 432 is formed over the etch stop layer 430. Another etch stop layer 434 is formed over the N− layer 432. An N+ layer 436 is formed over the etch stop layer 434.

The layers 436, 432, 428, 427, 422, 421 and 411 form a switching device 450, a plurality of which form the antenna switch described above. An isolation region 452, shown using a dotted line, is formed in the layers 436, 432, 428, 427, 422, 421 and a portion of the buffer layer 411. The isolation region 452 can be formed by, for example, implanting ions chosen from boron (B), oxygen (O), etc., in the approximate area shown as isolation region 452. The isolation region 452 isolates ohmic material 446 from the active portions of the transistor device 400.

Ohmic metal is deposited to form a drain 444 and a source 438. Similarly, after a suitable etching step down to the etch stop layer 430, gate metal is deposited to form a gate 442.

In accordance with an embodiment of the high frequency, low loss switch, the epitaxial structure is further etched down to the etch stop layer 410 so that metal 446 can be deposited to contact the conductive layer 405. The metal 446 can be, for example, an ohmic metal such as nickel (Ni), germanium (Ge), gold (Au), or another ohmic metal. The metal 446 can be applied as a thick metal 446 using metal evaporation, plating or other deposition systems to ensure adequate step height coverage. In this manner, an electrical contact is made through the epitaxial structure of the switch 450 down to the conductive layer 405 and the semi-insulating substrate 402.

The embodiment shown in FIG. 11 illustrates a completely integrated solution for coupling the capacitances to the substrate 402. The metal 446 can be ohmic metal, or can be a number of thick metal layers that are successively deposited. A voltage applied through the metal 446 and applied to the buried conductive layer 405 is used to linearize the parasitic capacitances of the transistor device, as described above.

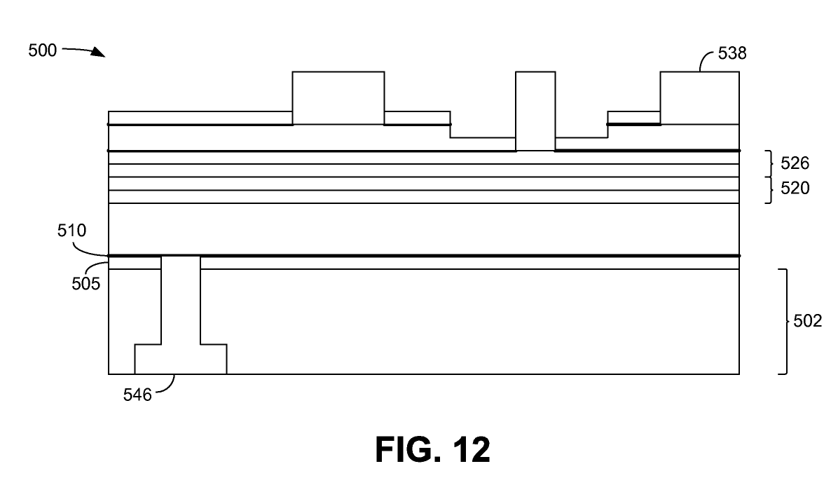

FIG. 12 is a cross-sectional diagram illustrating an alternative embodiment of a transistor device that can be used to fabricate a high frequency, low loss switch.

The transistor device 500 shown in FIG. 12 is similar to the transistor device 400 shown in FIG. 11. Therefore, layers of the device 500 that are similar to layers in the device 400 will be identified using the nomenclature 5XX, where the term “XX” refers to the corresponding element in FIG. 11. For example, the substrate 502 in FIG. 12 is similar to the substrate 402 in FIG. 11, and will not be described again.

The structure of the transistor device 500 is achieved by a process that is referred to as “backside processing.” Backside processing refers to processing steps that are applied to the epitaxial structure from the substrate side of the device. For example, in the transistor device 500, the substrate 502 undergoes a selective etch down to the etch stop layer 510. Then, metal 546 is deposited through the opening in the substrate down to the etch stop layer 510. In this manner, a voltage applied through the metal 546 and applied to the buried conductive layer 505 is used to linearize the parasitic capacitances of the transistor device, as described above.

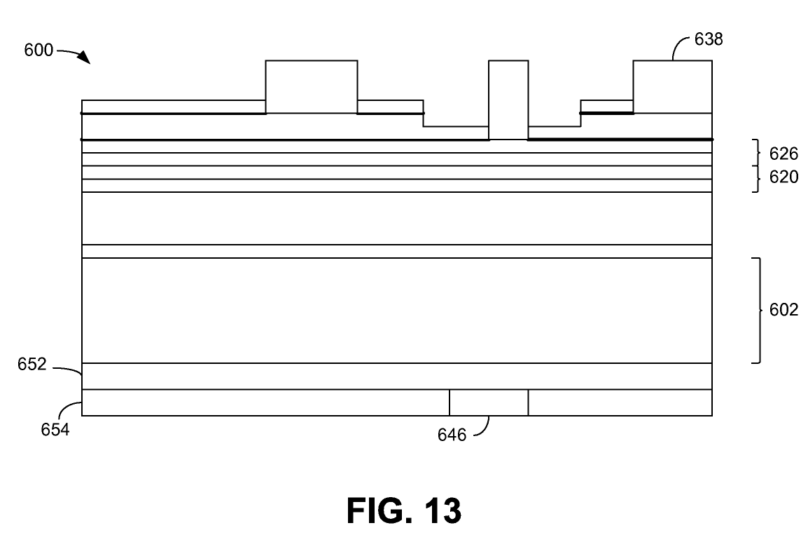

FIG. 13 is a cross-sectional diagram illustrating another alternative embodiment of a transistor device that can be used to fabricate a high frequency, low loss switch.

The transistor device 600 shown in FIG. 13 is similar to the transistor device 400 shown in FIG. 11. Therefore, layers of the device 600 that are similar to layers in the device 400 will be identified using the nomenclature 6XX, where the term “XX” refers to the corresponding element in FIG. 11. For example, the substrate 602 in FIG. 13 is similar to the substrate 402 in FIG. 11, and will not be described again.

The transistor device 600 includes a metal layer 652 and an insulating layer 654. In an embodiment, the metal layer 652 can be gold, copper or any typical metal used in semiconductor fabrication. The insulating layer 654 can be, for example, a nitride material. The insulating layer 654 should exhibit good thermal conductivity. A portion of the insulating layer 654 can be etched and metal 646 can be deposited so that the metal 646 contacts the metal layer 652.

Alternatively, any type of dielectric material can be used to cover the back side of the wafer (substrate 602) or the substrate 602 can be patterned and metalized to provide electrical contact to back-bias the parasitic capacitances, as described above.

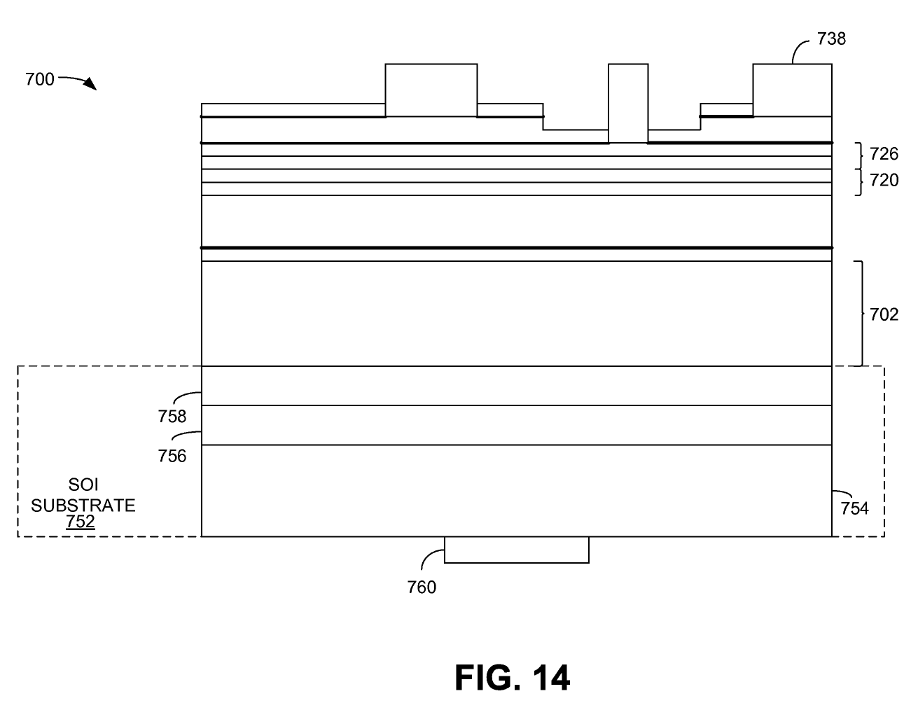

FIG. 14 is a cross-sectional diagram illustrating another alternative embodiment of a transistor device that can be used to fabricate a high frequency, low loss switch.

The transistor device 700 is formed on what is referred to as a “silicon-on-insulator” (SOI) substrate 752. The SOI substrate 752 generally includes an N+ semiconductor layer 754 over which is formed an insulating layer 756. The semiconductor layer 754 can be, for example, GaAs, silicon, or another material. The insulating layer 756 can be, for example, silicon dioxide, silicon nitride, or another insulating material. A semiconductor layer 758 is formed over the insulating layer 756. The semiconductor layer 758 can be, for example, gallium arsenide (GaAs), silicon, or another material. A metal bias contact 760 is formed on a surface of the N+ semiconductor layer 754. The bias contact 760 provides electrical contact to back-bias the parasitic capacitances, as described above.

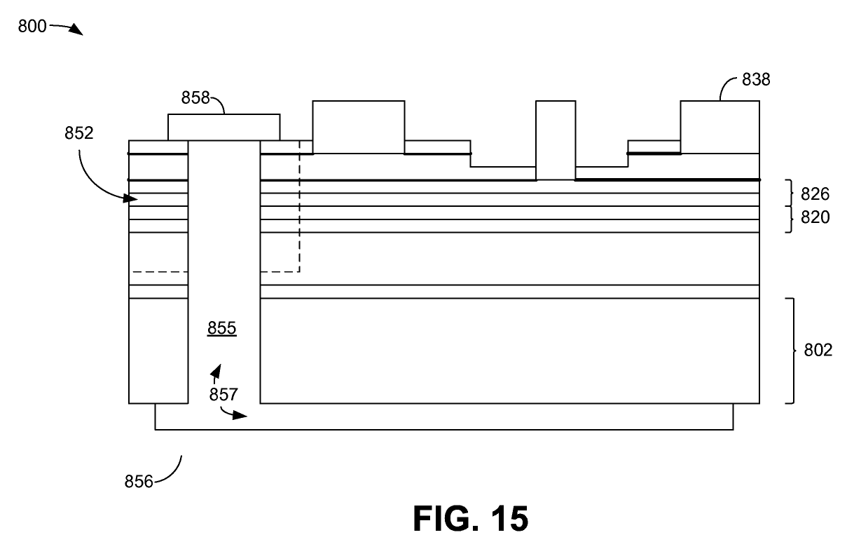

FIG. 15 is a cross-sectional diagram illustrating another alternative embodiment of a transistor device that can be used to fabricate a high frequency, low loss switch.

The transistor device 800 shown in FIG. 15 is similar to the transistor device 400 shown in FIG. 11. Therefore, layers of the device 800 that are similar to layers in the device 400 will be identified using the nomenclature 8XX, where the term “XX” refers to the corresponding element in FIG. 11. For example, the substrate 802 in FIG. 15 is similar to the substrate 402 in FIG. 11, and will not be described again.

The structure of the transistor device 800 is another example of backside processing. For example, in the transistor device 800, a via hole 855 is created in the layers of the device 800. The via hole 855 can be formed by etching, drilling, or other known via formation techniques. For example, the via hole 855 can be formed using reactive ion etching (RIE) or inductively coupled plasma (ICP) etching.

In this embodiment, once front side processing is completed, one or more via holes can be etched from the wafer's backside to an ohmic metal pad 858 on the wafers front side. The via hole 855 and the backside of the wafer can then be metallized 857 using processes such as sputtering, electroplating, or another process. The backside metal can be patterned and etched to ensure there is an appropriate non-metallized area at each die edge. A dielectric 856 can then be deposited onto the backside of the wafer. Materials such as a photo-imageable spin-on polyimide or silicon nitride could be used as the dielectric 856. The thin backside dielectric 856 isolates the backside metal from any conductive epoxy or underlying element while still providing adequate heat transfer properties.

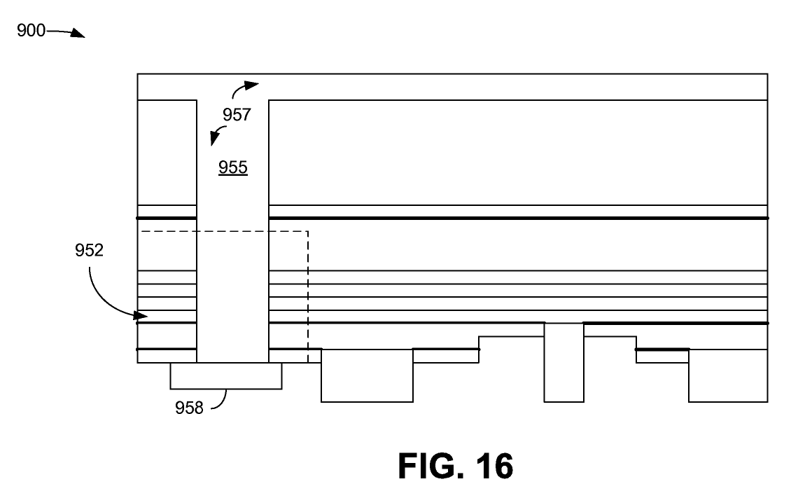

FIG. 16 is a cross-sectional diagram illustrating another alternative embodiment of a transistor device that can be used to fabricate a high frequency, low loss switch. The transistor device 900 shown in FIG. 16 is similar to the transistor device 800 shown in FIG. 15, but is illustrated as inverted to describe what is referred to as a “flip chip” mounting architecture. The transistor device 900 has a thru wafer via hole 955 to which metal 957 has been applied as described above. Because the device is a flip chip, backside dielectric is not used.

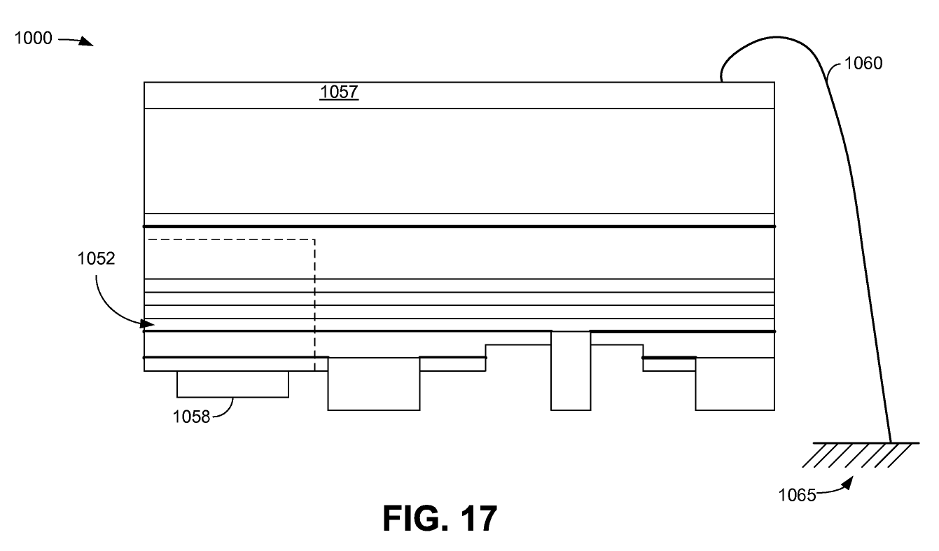

FIG. 17 is a cross-sectional diagram illustrating another alternative embodiment of a transistor device that can be used to fabricate a high frequency, low loss switch. The transistor device 1000 shown in FIG. 17 is similar to the transistor device 900 shown in FIG. 16. However, the transistor device 1000 includes a wire bond 1060 from the PCB 1065 to the backside metal 1057. The wirebond connection 1060 is used to apply the bias to the backside of the wafer.

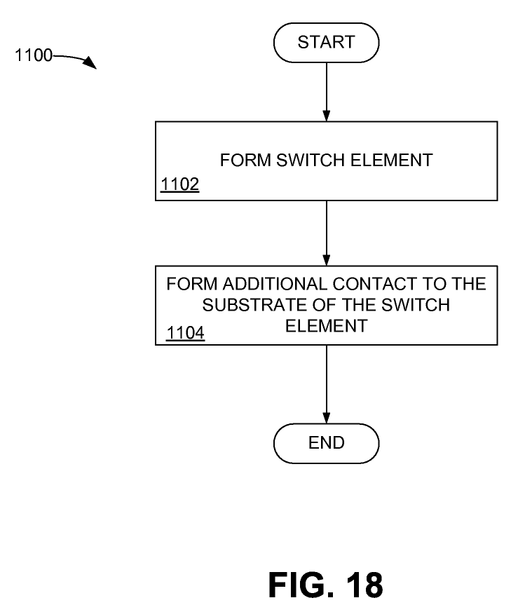

FIG. 18 is a flowchart illustrating an example of making an embodiment of a high frequency, low loss switch element.

In block 1102 a switch element is formed. In block 1104, an additional contact is formed in the switch element to provide electrical contact to the substrate of the switch element. The additional contact can be in the form of the two plate structure described in FIG. 8, can be in the form of the additional metal contact described in FIG. 11, 12, 13, 14, 15 or 16, or can be in the form of a wire bond described in FIG. 17.

While various embodiments of the invention have been described, it will be apparent to those of ordinary skill in the art that many more embodiments and implementations are possible that are within the scope of this invention. For example, the linearity enhancement technique described herein is applicable to all FET structures, including devices operating in a common-source and common-drain configuration (such as power amplifiers), in addition to the common-gate devices (such as switched) described herein.

What is claimed is:

1. A switch element, comprising:
a field effect transistor (FET) structure formed on a substrate, the FET structure having a drain, a gate and a source, the drain having a drain capacitance, the gate having a gate capacitance, the source having a source capacitance; and
an electrical connection to couple the drain capacitance, gate capacitance and the source capacitance to the substrate.

2. The switch element of claim 1, further comprising a thermally conductive connection from the FET structure to the substrate.

3. The switch element of claim 1, in which the electrical connection comprises a two plate structure.

4. The switch element of claim 1, in which the electrical connection comprises a metal connection within the FET structure, the metal connection formed to a conductive layer adjacent the substrate.

5. The switch element of claim 1, in which the electrical connection comprises a metal connection within the FET structure, the metal connection formed to a conductive layer adjacent the substrate, wherein the metal connection is formed through the substrate from a substrate side of the FET.

6. The switch element of claim 1, further comprising:
a metal layer formed over an exposed surface of the substrate; and
an insulating layer formed over the metal layer, in which the electrical connection comprises a metal connection within the FET structure, the metal connection formed to the metal layer, wherein the metal connection is formed through the insulating layer from a substrate side of the FET.

7. The switch element of claim 1, further comprising:
a silicon-on-insulator (SOI) substrate, in which the electrical connection comprises a metal connection to the SIO substrate.

8. The switch element of claim 1, further comprising:
a via hole formed through the FET structure;
a metal layer formed within the via hole and formed over an exposed surface of the substrate; and
an insulating layer formed over the metal layer, in which the electrical connection comprises a metal connection within the FET structure, the metal connection formed to the metal layer.

9. The switch element of claim 1, further comprising:
a metal layer formed over an exposed surface of the substrate; and
a wire bond connection to the metal layer, the wire bond connection configured to allow the application of an electrical bias to the metal layer.

10. A portable transceiver having an antenna switch, comprising:
a transmitter operatively coupled to a receiver;
a switch device operatively coupled to the transmitter and to the receiver, the switch device comprising at least one field effect transistor (FET) structure formed on a substrate, the FET structure having a drain, a gate and a source, the drain having a drain capacitance, the gate having a gate capacitance, the source having a source capacitance; and
an electrical connection to couple the drain capacitance, gate capacitance and the source capacitance to the substrate.

11. The transceiver of claim 10, in which the electrical connection comprises a metal connection within the FET structure, the metal connection formed to a conductive layer adjacent the substrate.

12. The transceiver of claim 10, in which the electrical connection comprises a metal connection within the FET structure, the metal connection formed to a conductive layer adjacent the substrate, wherein the metal connection is formed through the substrate from a substrate side of the FET.

13. The transceiver of claim 10, further comprising:
a metal layer formed over an exposed surface of the substrate; and
an insulating layer formed over the metal layer, in which the electrical connection comprises a metal connection within the FET structure, the metal connection formed to the metal layer, wherein the metal connection is formed through the insulating layer from a substrate side of the FET.

14. The transceiver of claim 10, further comprising:
a silicon-on-insulator (SOI) substrate, in which the electrical connection comprises a metal connection to the SIO substrate.

15. The transceiver of claim 10, further comprising:
a via hole formed through the FET structure;
a metal layer formed within the via hole and formed over an exposed surface of the substrate; and
an insulating layer formed over the metal layer, in which the electrical connection comprises a metal connection within the FET structure, the metal connection formed to the metal layer.

16. The transceiver of claim 10, further comprising:
a metal layer formed over an exposed surface of the substrate; and
a wire bond connection to the metal layer, the wire bond connection configured to allow the application of an electrical bias to the metal layer.

17. A method for making a switch element, comprising:
forming a field effect transistor (FET) structure on a substrate, the FET structure having a drain, a gate and a source, the drain having a drain capacitance, the gate having a gate capacitance, the source having a source capacitance; and
forming an electrical connection to couple the drain capacitance, gate capacitance and the source capacitance to the substrate.

18. The method of claim 17, in which forming the electrical connection further comprises forming within the FET structure a metal connection to a conductive layer adjacent the substrate.

19. The method transceiver of claim 17, in which forming the electrical connection further comprises forming within the FET structure a metal connection to a conductive layer adjacent the substrate, wherein the metal connection is formed through the substrate from a substrate side of the FET.

20. The method of claim 17, further comprising:
forming a metal layer formed over an exposed surface of the substrate; and
forming an insulating layer over the metal layer, in which forming the electrical connection further comprises forming within the FET structure a metal connection to the metal layer, wherein the metal connection is formed through the insulating layer from a substrate side of the FET.

21. The method of claim 17, further comprising forming a silicon-on-insulator (SOI) substrate, in which forming the electrical connection comprises forming a metal connection to the SIO substrate.

22. The method of claim 17, further comprising:
forming a via hole through the FET structure;
forming a metal layer within the via hole and over an exposed surface of the substrate; and
forming an insulating layer over the metal layer, in which the electrical connection comprises a metal connection within the FET structure, the metal connection formed to the metal layer.

23. The method of claim 17, further comprising:
forming a metal layer formed over an exposed surface of the substrate; and forming a wire bond connection to the metal layer, the wire bond connection configured to allow the application of an electrical bias to the metal layer.
